(19) United States
(12) Patent Application Publication
(10) Pub. No.: US 2010/0282292 A1
(43) Pub. Date: Nov. 11, 2010

(54) Structure and method for electrical interconnects for solar systems

(76) Inventor: Igor Jan Malik, Palo Alto, CA (US)

Correspondence Address: Igor J. Malik, 3310 Kenneth Drive, Palo Alto, CA, 94303, US

(21) Appl. No.: 12/799,967

(22) Filed: May 6, 2010

Related U.S. Application Data
(60) Provisional application No. 61/176,878, filed on May 8, 2009.

(51) Int. Cl. H01L 31/042; H01L 31/18

(52) U.S. Cl. 136/244; 438/66; 257/E31.11

(57) ABSTRACT

A novel electrical wiring for solar panels is provided. A first electrical grid overlies a front glass cover and a second electrical grid overlies a back cover, rather than photovoltaic cells. Conductive pads that are electrically connected to the back side of photovoltaic cells are integrated with the back member. A novel back side to front side electrical interconnect scheme between adjacent cells is provided. This overall new approach significantly improves solar PV system cost, efficiency, and reliability.

### BACKGROUND

PV (photovoltaic) solar systems offer a promising direction for switching from fossil (non-renewable) to renewable energy generation. The main obstacles to a wider adoption of solar PV systems are relatively high cost, low efficiency, and insufficient reliability of the state-of-the-art PV systems. This invention addresses all three problems, pointing the way to lower PV system cost, increased efficiency, and improved reliability.

### DESCRIPTION OF THE INVENTION

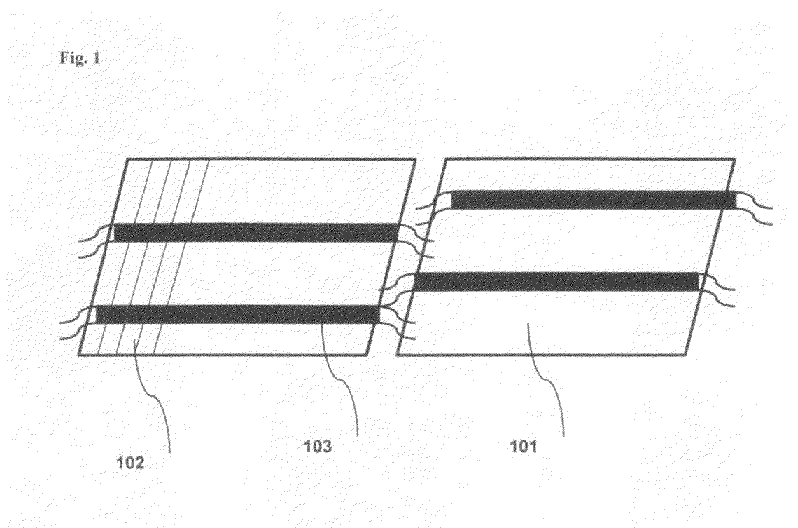

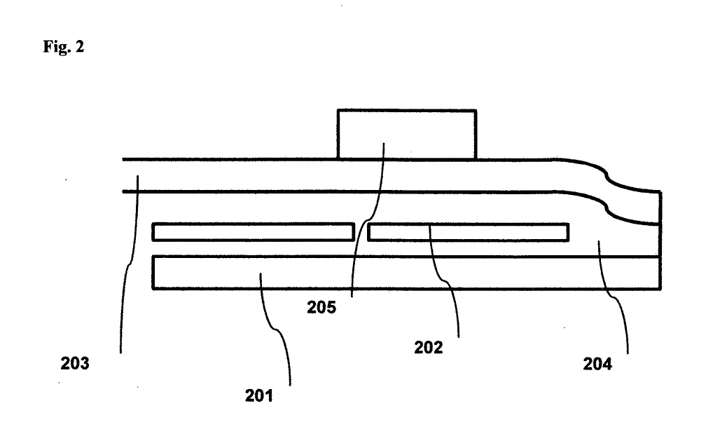

In the present state-of-the-art solar PV systems based on crystalline Si (c-Si), the collection of the charges generated from the interaction of solar radiation with the PV absorber material is accomplished through a grid of thin conductive “fingers” placed on the surface of the cells and thick “busbars” placed on the surface of the cells as well between cells. The fingers function as local interconnects (collecting charges from local areas of the cell, conducting relatively small currents), while the busbars provide global interconnects, collecting electric current from each of the fingers of a PV cell for a PV module. The PV module is usually completed using a lamination process when a flexible multi-layer backsheet is attached. FIGS. 1 and 2 depict this charge collection scheme and moduling respectively:

As shown in FIG. 1, a simplified diagram of a front surface of a conventional PV cell 101 is provided. The front surface has one or more fingers 102 and one or more busbars 103 arranged in a pre-determined pattern. Typically the fingers and the busbars are perpendicular to each other. In FIG. 2, the interconnected PV cells (201) are sandwiched between the front glass (202) and the backsheet (203), using EVA (204) as an optically transparent coupling agent. A junction box (205) is attached to the backsheet, allowing the PV-generated charges to be collected from the module. The EVA seal (204) and the junction box (205) are not hermetically sealed.

Limitations of the conventional process for the manufacture of c-Si solar PV modules are many. They include high manufacturing cost, due to both a relatively complex process as well as expensive materials. Another disadvantage is related to shadowing of the active PV area by the conductive grid. As can be seen in FIG. 1, both the optically opaque fingers (102) and busbars (103), prevent solar radiation from reaching the underlying active PV material and generating the desired electron-hole pairs. Another disadvantage of the conventional processing scheme is the compromised long-term reliability of the module, as can be seen from FIG. 2. This is due to the fact that the EVA seal 204 as well as the junction box attachment (205) are not hermetically sealed, allowing a slow inflow of gases and moisture into the PV module. Since the solar PV modules typically carry a 25-year warranty, penetration of gases or moisture into the module can and does cause materials degradation, e.g., conductor corrosion.

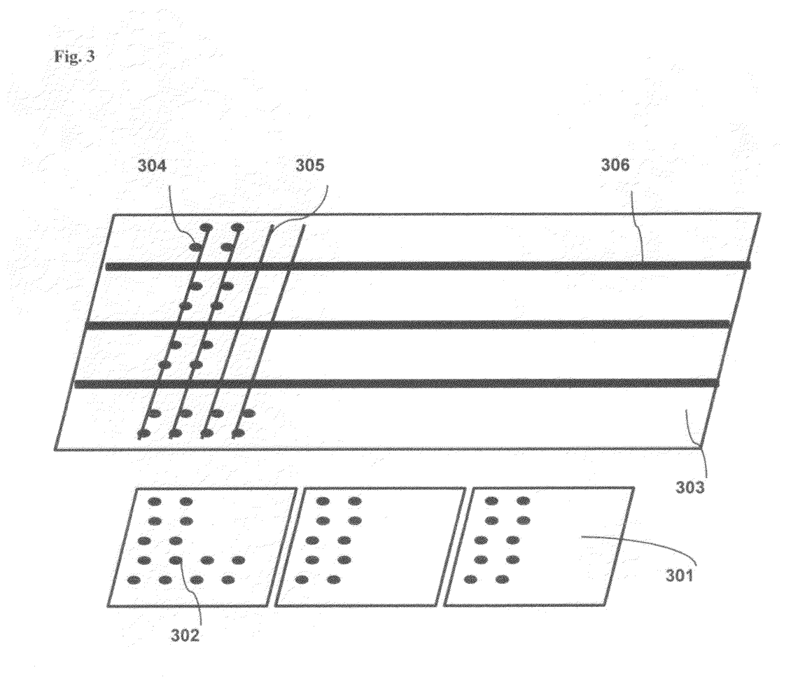

Therefore, it is highly desirable to address the problems of the present solar PV module manufacturing process described above. Embodiments according to the present invention are exemplified in FIGS. 3-5 and the description throughout the specification and particularly below. Of course one skilled in the art would recognize many other variations, modifications, and alternatives.

FIG. 3 illustrates a photovoltaic cell structure 300 according to an embodiment of the present invention. As shown the photovoltaic cell structure includes one or more photovoltaic cells 301 for decoupling the global interconnects (charge collection on the cell-level and module-level) from the PV cells. As shown, a photovoltaic cell 301 is provided. Each of the plurality of photovoltaic cells may be made of a crystalline silicon material, an amorphous silicon material, a thin film material such as CIGS or CdTe, an organic solar material, a dye-sensitized solar material, or a solar ink material. In a specific embodiment, each of the photovoltaic cell includes a first conductor structure 302 overlying each of the photovoltaic cell. The first conductor structure provides charge collection points for the PV module. In other embodiments, conductor fingers maybe used. The charge collection points favorably reduce the shadowed area of the PV cell surface. Front glass 303 is functionalized by incorporation of the conductors for charge collection on a local as well as global module scale. Conductive “landing pads” 304 on the glass are connected during the moduling process to the “charge collection points” on the cell to allow charge transfer (electrical current) between the PV absorber (the bulk material of the cell) and the functionalized glass that now includes a network of conducting paths. Landing pads 304 are connected using thin conductors 305. Thin conductors 305 are connected to thick conductors 306 (commonly known as bus bars) which conduct the current over the cells as well as between the cells. The role of thin conductors 305 and thick conductors 306 can be combined in a scheme that integrates the local and global interconnects. In certain embodiments, the bus bars are configured to be above spatial regions between adjacent solar cells. The spatial regions are void regions in a specific embodiment. Of course there can be other variations, modifications, and alternatives.

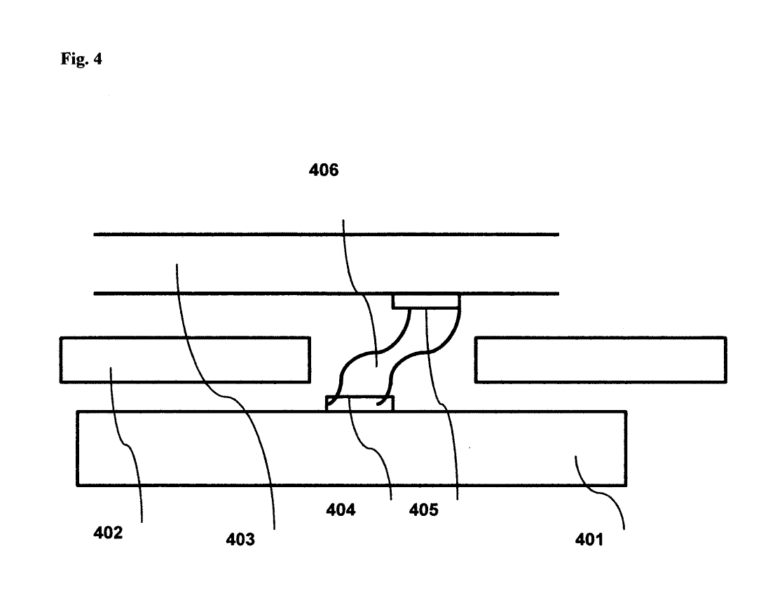

Further, the solar cells are usually connected in series within the module. The series configuration results in a high module voltage since voltage is additive for a series-connected solar cell array. In order to connect equivalent cells in series, one needs to connect the top electrode of one cell to the bottom electrode of the neighboring cell. FIG. 4 illustrates how to accomplish this: Front glass 401 has a front-side interconnect grid deposited or attached on the inside (toward the cells, inside of the module). Cells 402 are located between a functionalized front glass 401 and a back cover 403 which can be glass, or a backsheet. The back cover is functionalized on the inside (toward the back side of the cells, inside of the module) with the conductors in a similar way as the front glass (but accounting for the differences in the cell wiring between their front- and back-sides). Both the front glass and the back cover have conductive landing pads—(404) and (405), respectively. A flexible conductor that allows for reliability and manufacturability of electrical connection between the landing pads (404) and (405) connects the front side and back side conductive grids.

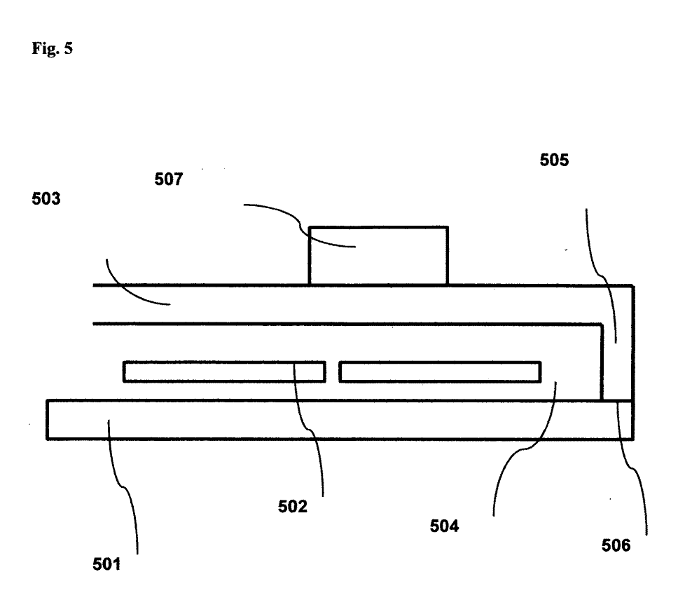

FIG. 5 illustrates a structure and process that allows hermetic sealing of the solar PV module according to an embodiment of the present invention. The PV cells (502) are sandwiched between the front glass (501) and the back cover (preferably glass) (502). An optically transparent adhesive (504), like EVA, is used to keep the PV module components from moving with respect to each other. Glass is used as the back cover (503) in FIG. 5. The back glass has a thicker region around its periphery (a “frame”) (505) that allows a hermetic seal (506) to be made and completely isolate the inside of the module from the outside environment. Alternately, the “frame” can be on the front glass, on both the front glass and the back cover, or it can be a separate part. There are multiple techniques that can be used to make the hermetic seal, including laser welding and glass frit bonding. Finally, the junction box (507) is also hermetically sealed to maintain the separation between the inside of the module and the surrounding ambient.

The embodiments described above address three major problems of the current state-of-the-art solar PV module manufacturing: cost, efficiency, and reliability. Routing the PV current through a conductor grid created on the front glass and back cover (preferably glass) lowers the cost by eliminating the tabbing and stringing processes with the glass-functionalization or metallization step. In addition to that, it opens the door for using thinner solar wafers than are being currently used. Thinner wafers are easier to break or chip in the tabbing & stringing operation. This invention allows for even significantly thinner wafers to be placed on the front glass for electrical interconnection without the mechanically demanding tabbing & stringing process. The potential for using significantly thinner wafers points toward significant cost savings.

In addition to PV systems based on c-Si (crystalline silicon) cells, this invention can be used for PV systems based on thin film solar cells, e.g., a-Si (amorphous Si), CIGS/CIS (copper indium gallium selenide/ copper indium selenide), CdTe (cadmium telluride), organic cells, dye-sensitized cells, solar ink cells, as well as others.

Embodiments according to the present invention are particularly effective for PV systems using a large-area front glass. The examples of manufacturers using large-area glass include Oerlikon, Applied Materials (so called Generation 8 glass substrate), and Sharp (so called Generation 10 glass substrate). The large-area front glass can be used in conjunction with a wide variety of solar cells, including c-Si, a-Si, CIGS/CIS, CdTe, organic cells, dye-sensitized cells, solar ink cells, as well as others.

Depending on the embodiment, this invention can be used for electrical wiring on one side only (front or back) of the PV module, or on both sides. The first example of an application of this invention to the front-side only is a PV module based on standard p-type c-Si cells; the back side can be processed according to the state-of-the-art technology (backside conductive plane, busbars, backsheet). The second example is an application to the backside only: PV systems based on high-efficiency n-type solar cell have often electrical contacts with metallization on the back side only (e.g., PV modules by SunPower). In this case, the invention can be applied to the backside only, with the front side needing no metallization.

It is also understood that the examples and embodiments described herein are for illustrative purposes only and that various modifications or alternatives in light thereof will be suggested to persons skilled in the art and are to be included within the spirit and purview of this application and scope of the appended claims.

What is claimed:

1. A PV module structure comprising:
a plurality of solar cells, each of the solar cells comprising a first plurality of conductor elements and a second plurality of conductor elements;
a front transparent member, the front transparent member having a surface region and a back surface region;
a first conductor structure overlying the back surface region of the front transparent member;
a back cover member, the back cover member having a first surface region and a first back surface region,
a second conductor structure overlying the first surface region of the back cover member;
a seal region provided in a peripheral region of the front transparent member and the back cover member to provide a hermetic environment for the plurality of solar cells and
wherein each of the first plurality of conductor pads is coupled to the first conductor structure, and
wherein the second plurality of conductor pads is coupled to the second conductor structure.

2. The module of claim 1 wherein each of the plurality of solar cells comprises a photovoltaic material selected from: crystalline silicon material, amorphous silicon material, thin film material such as CIGS or CdTe, organic solar material, dye-sensitized solar material, or solar ink material.

3. The module of claim 1 wherein the photovoltaic material is a p-type crystalline material.

4. The module of claim 1 wherein the front transparent member comprises an inorganic glass material.

5. The module of claim 1 wherein the front transparent member comprises an organic polymer material.

6. The module of claim 1 wherein the first conductor structure is optional.

7. The module of claim 1 wherein the second conductor structure is optional.

8. The module of claim 1 wherein the first conductor structure and the second conductor structure comprise at least one bus bar.

9. The module of claim 1 wherein the bus bar is provided above a spatial region between solar cells, the spatial regions are void regions.

10. The module of claim 1 wherein the back cover member comprises a glass material.

11. The module of claim 1 wherein the back cover member comprises a backsheet.

12. The module of claim 1 wherein the first conductor structure and the second conductor structure is provided using a metallization process.

13. The module of claim 1 wherein the first conductor elements and the second conductor elements provide charge collector points for the solar cell.

14. The module of claim 1 wherein the first conductor structure comprises a plurality of landing pads.

15. The module of claim 1 wherein the second conductor structure comprises a plurality of landing pads.

16. The module of claim 1 wherein the entire module structure is sealed using, e.g., glass frit, or laser processing.

17. The module of claim 1 further comprises a hermetically sealed junction box.

18. The module of claim 1 wherein the front transparent member is a glass having a dimension of about 1.4 m², manufactured by Oerlikon Solar.

19. The module of claim 1 wherein the front transparent member is a glass having a dimension of about 1.6 m², to provide for e.g., a standard crystalline silicon 6×10 module with 156 mm cells.

20. The module of claim 1 wherein the front transparent member is a glass having a dimension of about 5.7 m², to provide for e.g., Applied Material solar module.

21. The module of claim 1 wherein the front transparent member is a glass having a dimension of about 5.7 m², e.g., a Sharp Gen 10 LCD glass size.

22. A method for manufacturing a solar module, comprising:
providing a plurality of solar cells, each of the solar cells comprising a first plurality of conductor elements and a second plurality of conductor elements;
providing a front transparent member, the front transparent member having a surface region and a back surface region;
forming a first conductor structure overlying the back surface region of the front transparent member;
providing a back cover member, the back cover member having a first surface region and a first back surface region,
forming a second conductor structure overlying the first surface region of the back cover member;
forming a seal region provided in a peripheral region of the front transparent member and the back cover member to provide a hermetic environment for the plurality of solar cells and
wherein each of the first plurality of conductor pads is coupled to the first conductor structure, and
wherein the second plurality of conductor pads is coupled to the second conductor structure.
